(19) United States
(12) Patent Application Publication
(10) Pub. No.: US 2006/0292769 A1
(43) Pub. Date: Dec. 28, 2006

(54) MULTILAYERED STRUCTURE FORMING METHOD

(75) Inventors: Kenji Wada, Fujimi (JP); Tsuyoshi Shintate, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 11/425,762

(22) Filed: Jun. 22, 2006

(30) Foreign Application Priority Data
Jun. 23, 2005 (JP) 2005-182974

(51) Int. Cl. H01L 21/338

(52) U.S. Cl. 438/179

(57) ABSTRACT

A multilayered structure forming method includes disposing a dummy post on a first insulating pattern as a first inkjet process, disposing a second insulating pattern on the first insulating pattern as a second inkjet process so as to allow the second insulating pattern to surround a side surface of the dummy post, and disposing a first conductive pattern on the second insulating pattern a third inkjet process so as to connect the first conductive pattern to the dummy post. In this method, the first inkjet process includes a process for ejecting a functional liquid containing a first conductive material having high adhesiveness to the first conductive pattern onto the first insulating pattern.

### BACKGROUND

1. Technical Field

The present invention relates to a multilayered structure forming method, and more particularly to a multilayered structure forming method suitable for the use of an inkjet process.

2. Related Art

Much attention has been focused on a method for producing a wiring substrate or a circuit board by using an additive process with a printing technology. One reason for this is that the additive process is less costly than a traditional production method that repeats a process for applying thin-film coatings and a photolithographic process.

One of technologies used in such an additive process is inkjet process. For example, JP-A-2004-6578 has disclosed a conductive pattern forming method using an inkjet process.

JP-A-2004-6578 is an example of related art.

The inkjet process enables production of a multilayered structure by laminating a plurality of insulating patterns and a plurality of wiring patterns. However, a certain combination of a material of the wiring metal patterns and a material of the insulating patterns can cause poor adhesiveness between the mutually laminated patterns. Thus, selection of a material combination showing poor adhesiveness would result in separation between underlying patterns and the remaining patterns among the mutually laminated metallic and insulating patterns.

This problem especially occurs more frequently when either an insulating pattern or a metallic pattern forms the top surface layer of a multilayered structure. For example, an electronic component such as an LSI bare chip, an LSI package or a connector may be connected to the metallic pattern forming the top surface layer. In this case, an external force directed to the outside of the multilayered structure may act on the metallic pattern via a connection point therebetween. Then, if the external force works that way, the metallic pattern will be more easily separated from an underlying insulating pattern.

### SUMMARY

An advantage of the present invention is to provide an adhesive multilayered structure forming method by using an inkjet process.

According to a first aspect of the invention, a multilayered structure forming method includes a first inkjet process for disposing a dummy post on a first insulating pattern, a second inkjet process for disposing a second insulating pattern on the first insulating pattern so as to allow the second insulating pattern to surround a side surface of the dummy post, and a third inkjet process for disposing a first conductive pattern on the second insulating pattern so as to connect the first conductive pattern to the dummy post. In this method, the first inkjet process includes a process for ejecting a functional liquid containing a first conductive material having high adhesiveness to the first conductive pattern onto the first insulating pattern.

According to the characteristics of the method above, since the dummy post is disposed by the inkjet process, the dummy post has a tapered cross-sectional configuration. The side surface of the dummy post having such a configuration is surrounded by the second insulating pattern. Accordingly, the dummy post is fixed to the second insulating pattern. On the other hand, according to the characteristics above, the first conductive pattern is adhered to the dummy post. Therefore, the first conductive pattern is fixed with respect to the second insulating pattern.

Preferably, the second inkjet process includes a process for ejecting one of a functional liquid containing a predetermined insulating material having high adhesiveness to the first insulating pattern and a functional liquid containing a precursor of the predetermined insulating material having high adhesiveness to the first insulating pattern onto the first insulating pattern.

According to the characteristics above, the second insulating pattern can be adhered to the first insulating pattern as a base. Here, as described above, the first conductive pattern is fixed with respect to the second insulating pattern because of the dummy post. Thus, the first conductive pattern is also fixed with respect to the first insulating pattern farther below.

In the above aspect of the invention, the multilayered structure forming method may further include a fourth inkjet process for disposing the first insulating pattern on an object surface.

According to the characteristics above, the first insulating pattern is disposed by the inkjet process. Therefore, this can reduce material consumption in forming a multilayered structure.

Preferably, the first insulating pattern is comprised of a same material as the predetermined insulating material.

According to the characteristics above, the first insulating pattern and the second insulating pattern are adhered to each other.

Preferably, the first conductive material is same as a material of the first conductive pattern. More preferably, the first conductive material includes a same metal as the first conductive pattern.

According to the characteristics above, the dummy post and the first conductive pattern are adhered to each other.

In the above first aspect of the invention, the multilayered structure forming method may include a fifth inkjet process for disposing a conductive post on a second conductive pattern disposed on the object surface, the fourth inkjet process for disposing the first insulating pattern on the object surface so as to allow the first insulating pattern to cover the second conductive pattern and surround a lower part of a side surface of the conductive post, the second inkjet process for disposing the second insulating pattern on the first insulating pattern so as to allow the second insulating pattern to surround a remaining part of the side surface of the conductive post and the side surface of the dummy post and the third inkjet process for disposing the first conductive pattern on the second insulating pattern so as to connect the first conductive pattern to the conductive post and the dummy post.

According to the characteristics above, the method can provide a multilayered structure in which the first conductive pattern is not easily separated.

In the above aspect of the invention, the third inkjet process may include a process for disposing a connection land as the first conductive pattern.

According to the characteristics above, a connection land can be obtained that cannot be easily separated from the base.

In the above aspect of the invention, the third inkjet process may include a process for disposing a top surface layer of a multilayered structure as the first conductive pattern.

According to the characteristics above, a connection land can be obtained that cannot be easily separated from the base even if an external force is applied thereto.

According to a second aspect of the invention, a multilayered structure forming method includes a first inkjet process for disposing a dummy post and a second insulating pattern surrounding a side surface of the dummy post and a second inkjet process for disposing a first conductive pattern on the second insulating pattern so as to connect the first conductive pattern to the dummy post. In this method, the first inkjet process includes (a) a first process for forming a layer of a functional liquid by ejecting one of the functional liquid containing a predetermined insulating material and the functional liquid containing a precursor of the predetermined insulating material onto a first insulating pattern, and (b) a second process for forming a dummy post precursor by ejecting a functional liquid containing a first conductive material having high adhesiveness to the dummy post onto the layer of the functional liquid. In an embodiment of the second aspect of the invention, the first inkjet process may further include (c) a third process for activating the layer of the functional liquid and the dummy post precursor simultaneously so as to obtain the second insulating pattern from the layer of the functional liquid and the dummy post from the dummy post precursor, respectively.

According to the characteristics of the method above, since the dummy post is disposed by the inkjet process, a cross-sectional configuration of the dummy post becomes tapered. Additionally, since the side surface of such a dummy post is surrounded by the second insulating pattern, the dummy post is fixed to the second insulating pattern. On the other hand, according to the characteristics above, the first conductive pattern and the dummy post are adhered to each other. Therefore, the first conductive pattern is also fixed with respect to the second insulating pattern.

Preferably, the first process includes a process for ejecting one of the functional liquid containing the predetermined insulating material having high adhesiveness to the first insulating pattern and the functional liquid containing the precursor of the predetermined insulating material having high adhesiveness to the first insulating pattern onto the first insulating pattern.

According to the characteristics above, the second insulating pattern can be adhered to the first insulating pattern as the base. Here, as described above, the first conductive pattern is fixed with respect to the second insulating pattern because of the dummy post. Therefore, the first conductive pattern is also fixed with respect to the first insulating pattern farther below.

In the above aspect of the invention, the above multilayered structure forming method may further include a third inkjet process for disposing the first insulating pattern on an object surface.

According to the characteristics above, since the first insulating pattern is disposed by the inkjet process, material consumption required to form the multilayered structure can be reduced.

Preferably, the first insulating pattern is comprised of a same material as the predetermined insulating material.

According to the characteristics above, the first insulating pattern and the second insulating pattern are adhered to each other.

Preferably, the first conductive material is same as a material of the first conductive pattern. More preferably, the first conductive material includes a same metal as the first conductive pattern.

According to the characteristics above, the dummy post and the first conductive pattern are adhered to each other.

According to a third aspect of the invention, a multilayered structure forming method includes a first inkjet process for disposing an uneven pattern on a conductive pattern disposed on a surface of a substrate and comprised of a first conductive material and a second inkjet process for disposing an insulating pattern covering the conductive pattern and the uneven pattern.

According to the characteristics above, arrangement of the uneven pattern increases adhesiveness of the insulating pattern with respect to the conductive pattern. As a result, the insulating pattern cannot be easily separated from the conductive pattern.

### BRIEF DESCRIPTION OF THE DRAWINGS

The invention will be described with reference to the accompanying drawings, wherein like numbers reference like elements.

FIG. 1 shows a schematic view of a liquid droplet ejecting apparatus used in a multilayered structure forming method according to a first embodiment of the invention.

FIGS. 2A and 2B each show a schematic view of a head of the liquid droplet ejecting apparatus according to the first embodiment of the invention.

FIG. 3 shows a functional block diagram illustrating a control unit in the liquid droplet ejecting apparatus according to the first embodiment of the invention.

FIGS. 4A to 4E show views illustrating an outline of the multilayered structure forming method according to the first embodiment of the invention.

FIGS. 5A and 5B show views illustrating the outline of the multilayered structure forming method according to the first embodiment of the invention.

FIGS. 6A to 6E show views illustrating the outline of the multilayered structure forming method according to the first embodiment of the invention.

FIGS. 7A to 7C each show a schematic view of a cross section of the multilayered structure according to the first embodiment of the invention.

FIGS. 8A to 8E show explanatory views of a multilayered structure forming method according to a second embodiment of the invention.

FIGS. 9A to 9C show explanatory views of a multilayered structure forming method according to a third embodiment of the invention.

FIG. 10A shows a schematic view illustrating a configuration of a dummy post in the first through third embodiments of the invention.

FIGS. 10B and 10C each show a schematic view illustrating a modified configuration of the dummy post in the first through third embodiments of the invention.

FIG. 11 shows a schematic view illustrating a cross-sectional configuration of the dummy post shown in FIG. 10B.

### DESCRIPTION OF EXEMPLARY EMBODIMENTS

Embodiments of the invention will be described below with reference to the accompanying drawings.

### First Embodiment

First, a description will be given of a structure of a liquid droplet ejecting apparatus used in a multilayered structure forming method according to a first embodiment of the invention.

1. Entire Structure of Liquid Droplet Ejecting Apparatus

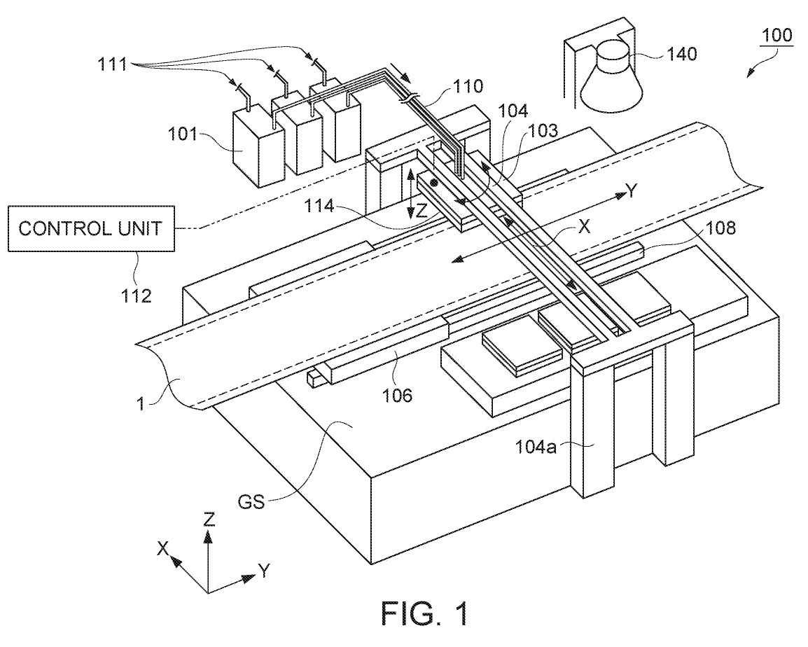

A liquid droplet ejecting apparatus 100 shown in FIG. 1 is basically an inkjet apparatus. More specifically, the liquid droplet ejecting apparatus 100 includes tanks 101 for storing liquid materials 111, tubes 110, a ground stage GS, an ejecting head unit 103, a stage 106, a first position controller 104, a second position controller 108, a control unit 112, a light irradiating device 140 and a supporting unit 104a.

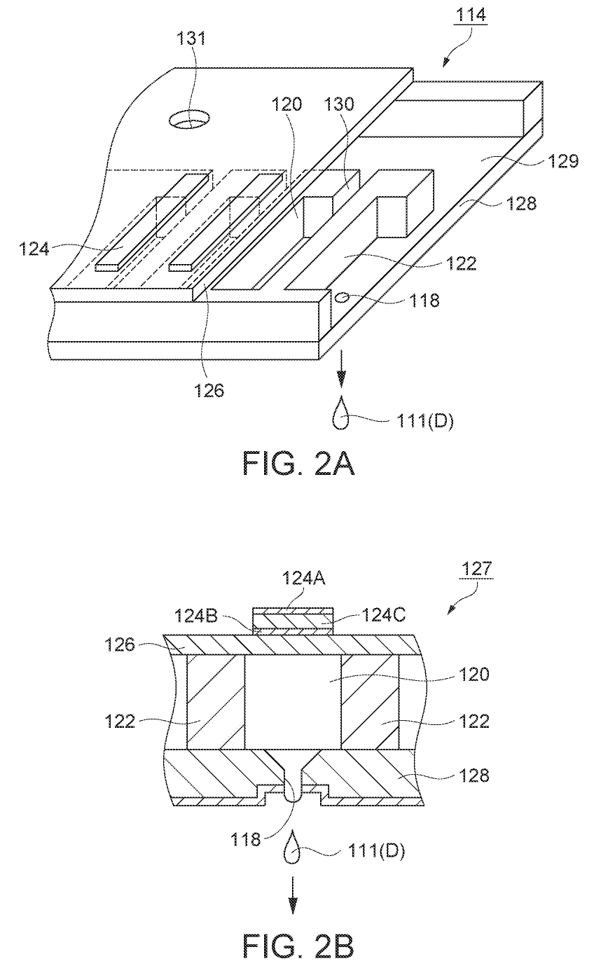

The ejecting head unit 103 has a head 114 (shown in FIG. 2). The head 114 ejects liquid droplets D of the liquid materials 111 in response to a signal from the control unit 112. In addition, the head 114 of the ejecting head unit 103 is linked to the tanks 101 via the tubes 110. Thus, the tanks 101 supply the liquid materials 111 to the head 114.

The stage 106 has a plane for fixing a substrate 1. Additionally, the stage 106 has a function to stabilize a position of the substrate 1 by using suction. As will be described later, here, the substrate 1 is a flexible substrate made of polyimide as a base substrate and has a tape-like configuration. Both ends of the substrate 1 are fixed to a pair of reels, which are not shown in the figure.

The first position controller 104 is fixed at a predetermined height from the ground stage GS by the supporting unit 104a. The first position controller 104 has a function to move the ejecting head unit 103 in an X-axial direction and a Z-axial direction orthogonal to the X-axial direction in response to a signal from the control unit 112. Furthermore, the first position controller 104 also has a function to rotate the ejecting head unit 103 around an axis parallel to the Z axis. Here in this embodiment, the Z-axial direction indicates a direction parallel to a vertical direction (namely, a gravity acceleration direction).

The second position controller 108 moves the stage 106 on the ground stage GS in a Y-axial direction in response to a signal from the control unit 112. Here, the Y-axial direction indicates a direction orthogonal to both of the X- and Z-axial directions.

Structures of the first and second position controllers 104 and 108 having the functions as described above can be realized by a well-known XY robot using a linear motor and a servomotor. Accordingly, a detailed explanation of the structures will not be given here. Additionally, in this specification, each of the first and second position controllers 104 and 108 may be referred to also as a “robot” or a “scanning unit”.

Now, as described above, the first position controller 104 moves the ejecting head unit 103 in the X-axial direction. Then, the second position controller 108 moves the substrate 1 together with the stage 106 in the Y-axial direction. Consequently, this changes a relative position of the head 114 with respect to the substrate 1. More specifically, because of the operations, the ejecting head unit 103 and the head 114 with nozzles 118 (shown in FIG. 2) move relatively with respect to the substrate 1 in the X- and Y-axial directions, that is, perform scanning relatively thereto, while maintaining a predetermined distance from the substrate 1 in the Z-axial direction. Here, the “relative movement” or “relative scanning” means that at least one of the part that ejects the liquid material 111 and the part (liquid-ejected part) where the material from the ejecting unit is dropped moves relatively with respect to the other part.

The control unit 112 is structured in a manner that receives ejection data showing relative positions where the liquid droplets D of the liquid materials 111 should be ejected from an external data processing apparatus. The control unit 112 stores the received ejection data in an internal storage device and controls the first and second position controllers 104, 108 and the head 114 in accordance with the stored ejection data. Here, the ejection data indicates data for supplying the liquid materials 111 on the substrate 1 in a predetermined pattern. In the first embodiment, the ejection data is formed in a bitmap data format.

In accordance with the ejection data, the liquid droplet ejecting apparatus 100 having the above structure, moves the nozzles 118 (shown in FIG. 2) of the head 114 relatively with respect to the substrate 1 and ejects the liquid materials 111 from the nozzles 118 onto the substrate 1 or a base body 10A (as described below). The relative movement of the head 114 by the liquid droplet ejecting apparatus 110 and the ejection of the liquid materials 111 from the head 114 may be referred to collectively as “liquid application scanning” or “ejection scanning”.

In the specification, a part where the droplets of the liquid materials 111 are dropped may be referred to also as a “liquid-ejected part”. Additionally, a part where the ejected liquid wet-spreads may be termed also as an “liquid-applied part”. Both of the liquid-ejected part and the liquid-applied part are also parts formed by performing a surface modification process on an object surface so that the liquid materials 111 can form a desired contact angle. Meanwhile, without performing any surface modification process, when the object surface has a desired lyophobic or lyophilic property with respect to the liquid material 111 (that is, when the dropped liquid material 111 forms a desired contact angle on the object surface), the object surface itself may be regarded as the “liquid-ejected part” or the “liquid-applied part”.

Referring now back to FIG. 1, the light irradiating device 140 is a device for irradiating ultraviolet light to the liquid materials 111 supplied on the substrate 1. The control unit 112 performs ON and OFF control of the light irradiating device 140 to allow irradiation of ultraviolet light.

2. Head

As shown in FIGS. 2A and 2B, the head 114 of the liquid droplet ejecting apparatus 100 is an inkjet head having a plurality of nozzles 118. Specifically, the head 114 includes a vibration plate 126, the plurality of nozzles 118, a nozzle plate 128 for defining each opening of the plurality of nozzles 118, a liquid reservoir 129, a plurality of partitions 122, a plurality of cavities 120 and a plurality of vibrators 124.

The liquid reservoir 129 is disposed between the vibration plate 126 and the nozzle plate 128. The liquid reservoir 129 is constantly filled with the liquid materials 111 supplied via a hole 131 from an external tank which is not shown in the figures. In addition, the plurality of partitions 122 are also disposed between the vibration plate 126 and the nozzle plate 128.

Each of the cavities 120 is a part surrounded by the vibration plate 126, the nozzle plate 128 and a pair of the partitions 122. Since the cavities 120 are disposed corresponding to the nozzles 118, the number of the cavities 120 is equal to the number of the nozzles 118. The liquid materials 11I are supplied into the cavities 120 from the liquid reservoir 129 via a supplying opening 130 located between the pair of the partitions 122. In this embodiment, each of the nozzles 118 has a diameter of approximately 27 μm.

Now, each of the plurality of vibrators 124 is disposed on the vibration plate 126 in a manner corresponding to each of the cavities 120. Each of the vibrators 124 includes a piezo element 124C and a pair of electrodes 124A and 124B having the piezo element 124C therebetween. The control unit 112 applies a driving voltage between the pair of electrodes 124A and 124B, whereby the corresponding nozzle 118 ejects the liquid droplet D of the liquid material 111. Here, the material ejected from the nozzle 118 has a volume that is variable in a range between 0 and 42 pl (pico-litter). Additionally, the configuration of each nozzle 118 is adjusted in a manner that ejects the liquid droplet D of the liquid material 111 in the Z-axial direction.

In the specification, a part including one of the nozzles 118, the cavity 120 corresponding to the nozzle 118 and the vibrator 124 corresponding to the cavity 120 may be referred to as an “ejecting unit 127”. In this case, a single head 114 has the same number of the ejecting units 127 as that of the nozzles 118. Each of the ejecting units 127 may include an electric thermal conversion element instead of the piezo element. In other words, the ejecting unit 127 may have a structure for ejecting the liquid materials 111 by using material thermal expansion caused by the electric thermal conversion element.

3. Control Unit

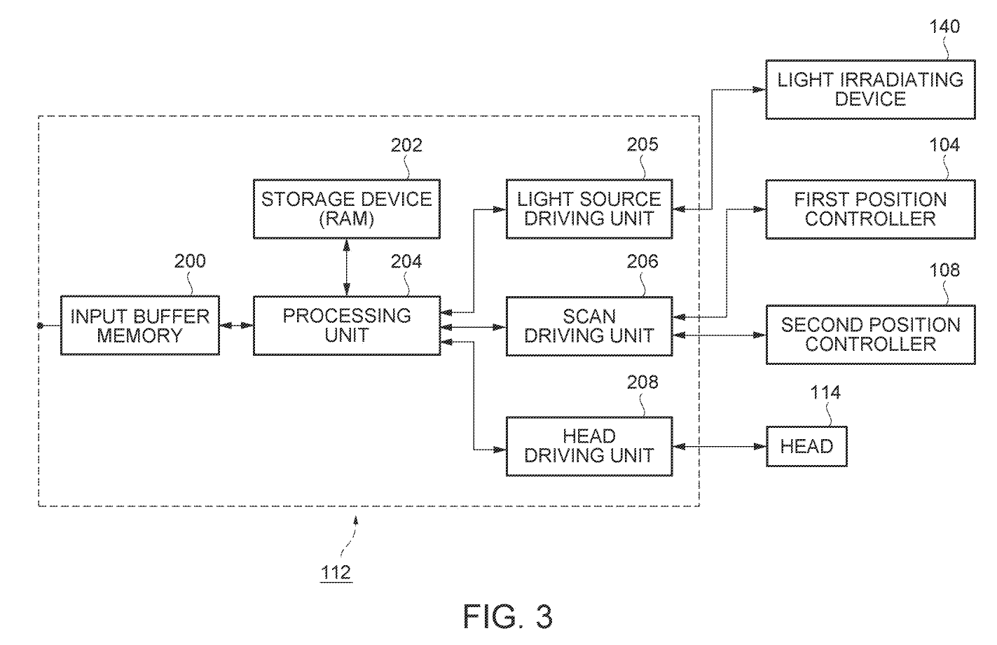

Next, a description will be given of a structure of the control unit 112. As shown in FIG. 3, the control unit 112 includes an input buffer memory 200, a storage device 202, a processing unit 204, a light source driving unit 205, a scan driving unit 206 and a head driving unit 208. Buses, which are not shown in the figure, connect the input buffer memory 200, the processing unit 204, the storage device 202, the light source driving unit 205, the scan driving unit 206 and the head driving unit 208 in a manner allowing mutual communication therebetween.

The light source driving unit 205 is connected to the light irradiating device 140 in a communicable manner. Additionally, the scan driving unit 206 is connected to the first and second position controllers 104 and 108 in a mutually communicable manner. Similarly, the head driving unit 208 is connected to the head 114 in a mutually communicable manner.

The input buffer memory 200 receives ejection data for ejecting the liquid droplets D of the liquid materials 111 from an external data processing apparatus (not shown in the figure) located outside the liquid droplet ejecting apparatus 100. The input buffer memory 200 supplies the ejection data to the processing unit 204, which in turn stores the ejection data in the storage device 202. In FIG. 3, the storage device 202 is Random Access Memory (RAM).

The processing unit 204 supplies data indicating a relative position of the nozzle 118 with respect to the liquid-ejected part to the scan driving unit 206 based on the ejection data stored in the storage device 202. The scan driving unit 206 supplies the data and a stage driving signal corresponding to a predetermined ejection cycle to the first and second position controllers 104 and 108. Consequently, this changes a relative position of the ejecting head unit 103 with respect to the liquid-ejected part. On the other hand, the processing unit 204 supplies an ejection signal necessary for ejecting each of the liquid materials 111 to the head 114 based on the ejection data stored in the storage device 202. As a result, the corresponding nozzle 118 of the head 114 ejects the liquid droplet D of the liquid material 111.

Furthermore, the processing unit 204 turns on or off the light irradiating device 140 based on the ejection data stored in the storage device 202. Specifically, the processing unit 204 supplies a signal indicating the on or off status of the light irradiating device 140 to the light source driving unit 205 so that the light source driving unit 205 can set the status thereof.

The control unit 112 is a computer including a CPU, a ROM, a RAM and buses. Thus, the above-mentioned functions of the control unit 112 are realized by the CPU performing a software program stored in the ROM. Obviously, the control unit 112 may be realized alternatively by an exclusive circuit (hardware).

4. Liquid Material

The above-mentioned “liquid material” means a material having a viscosity capable of being ejected as the liquid droplets D from the nozzles 118 of the head 114. Here, it is regardless whether the “liquid material” is water- or oil-based. It is enough for the liquid material to simply have liquidity (viscosity) allowing ejection from the nozzles 118. It is only necessary that the composition thereof be a liquid as a whole, even if a solid matter is contained therein. In this case, preferably, the “liquid material” has a viscosity between 1 and 50 mPa·s. In the case of a viscosity equal to or more than 1 mPa·s, it is unlikely that the peripheral parts of the nozzles 118 are contaminated by the “liquid materials” when the liquid droplets D thereof are ejected. On the other hand, a viscosity equal to or less than 50 mPa·s serves to reduce the incidence of blockage of the nozzles 118. Accordingly, the liquid droplets D can be ejected smoothly.

A functional liquid 14 (shown in FIGS. 6A to 6E), which will be described later, is a kind of the “liquid material”. The functional liquid 14 employed in the first embodiment contains a dispersion medium and silver as a conductive material. Here, the silver contained in the functional liquid 14 is composed of silver particles having a mean diameter of approximately 10 nm. Additionally, in the functional liquid 14, the silver particles are stably dispersed in the dispersion medium. The silver particles may be coated with a coating agent. In this case, the coating agent is a chemical compound that can form a coordinate bond with a silver atom.

Particles having a mean diameter between approximately 1 and a few hundred nanometers may be referred to as “nanoparticles”. According to the expression, the functional liquid 14 contains silver nanoparticles.

As the above-mentioned dispersion medium (or solvent), there is no particular limitation on the material to be used, as long as the material can disperse conductive micro particles such as silver particles and does not cause aggregation. For example, besides water, the material may be an alcohol such as methanol, ethanol, propanol or butanol, a hydrocarbon compound such as n-heptane, n-oxtane, decane, dodecane, tetradecane, toluene, xylene, cymene, durene, indene, dipentene, tetrahydronaphthalene, decahydronaphthalene or cyclohexylbenzene, an ether compound such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxy ethane, bis(2-methoxy ethyl)ether or p-dioxane, or a polar compound such as propylene carbonate, gamma-butyrolactone, N-methyl-2-pyrrolidone, dimethyl formamide, dimethyl sulfoxide or cyclohexanone. Among them, water, alcohols, hydrocarbons and ether compounds are more preferable in terms of the dispersibility of conductive microparticles, the stability of a dispersion liquid and easier application to the inkjet process. Furthermore, water and hydrocarbon compounds may be used as a more preferable dispersion medium.

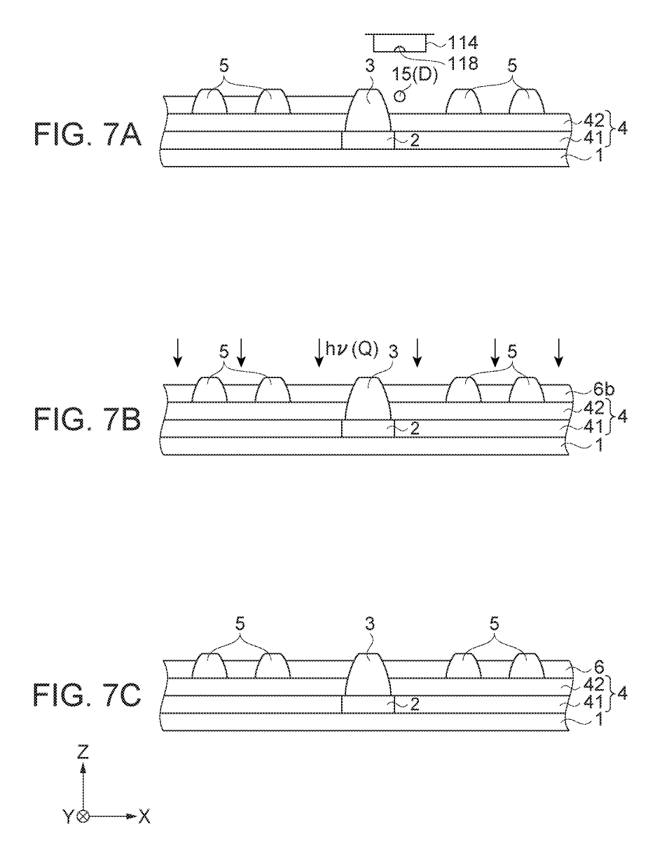

In addition, a functional liquid 15 (shown in FIGS. 7A to 7C), which will be described later, is also a kind of the “liquid material”. The functional liquid 15 employed in the first embodiment contains a solvent and an acrylic photosensitive resin as an insulating material. In the functional liquid 15, the acrylic photosensitive resin is dissolved in the solvent. It should be understood that the insulating material contained in the functional liquid 15 may be, as an alternative to the acrylic photosensitive resin, another insulating resin having photo-curing properties, an insulating resin having thermal curing properties or a precursor of any of these insulating resins.

5. Multilayered Structure Forming Method

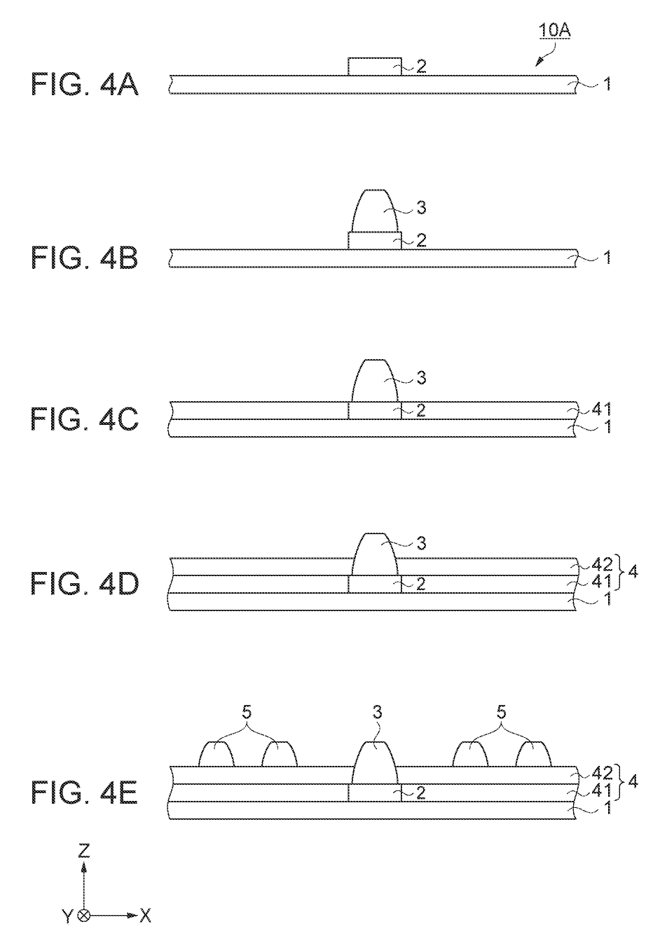

Referring to FIGS. 4A-4E to FIGS. 7A 7C, a description will be given of the multilayered structure forming method according to the first embodiment of the invention.

First, a base body 10A as shown in FIG. 4A is prepared. The base body 10A includes a substrate 1 and a conductive pattern 2 disposed thereon. Here, the substrate 1 is a flexible substrate made of polyimide. The substrate 1 has a tape-like configuration, and thus, may be referred to also as a “tape substrate”. In this specification, the “base body 10A” is a general term in which the substrate 1 and one or more patterns or layers disposed thereon are integrated. Moreover, in the specification, for illustrative convenience, a surface of the substrate 1 is set in parallel to both of the above-mentioned X and Y- axial directions.

Next, as shown in FIG. 4B, a conductive post 3 is disposed at a part on the conductive pattern 2 by the inkjet process. Here, details of a method for forming the conductive post 3 is basically the same as those of a method for forming a dummy post 5 to be described below. Additionally, the conductive post 3 in the first embodiment is made of silver.

After the formation of the conductive post 3, an insulating pattern 4 is disposed by the inkjet process, as shown in FIGS. 4C and 4D. The disposed insulating pattern 4 surrounds a lower part of a side surface of the conductive post 3 and also covers the conductive pattern 2. As will be explained below, the insulating pattern 4 is composed of mutually laminated two insulating sub-patterns 41 and 42. Such an insulating pattern 4 is a kind of “a first insulating pattern” employed in the present invention. The insulating pattern 4 will be formed as below.

First, using an “inkjet sub-process”, which will be described later, the insulating sub-pattern 41 is disposed at a part where the conducting pattern 2 is not disposed on the substrate 1 (See FIG. 4C). Here, a thickness of the insulating sub-pattern 41 is set approximately equal to that of the conductive pattern 2. Consequently, after the formation of the insulating sub-pattern 41, a surface of the insulating sub-pattern 41 is positioned at an approximately same level as that of the conductive pattern 2. Additionally, the insulating sub-pattern 41 of the embodiment contains acrylic rein.

Next, the insulating sub-pattern 42 is disposed by the “inkjet sub-process” on the surface where the conductive pattern 2 and the insulating sub-pattern 41 are formed (See FIG. 4D). Here, the insulating sub-pattern 42 is disposed in a manner that covers the underlying conductive pattern 2 and insulating sub-pattern 41 and surrounds a lower part of a side surface of the conductive post 3. Additionally, the insulating sub-pattern 42 contains acrylic resin.

Now, the “inkjet sub-process” is a process in which a layer, a film or a pattern is disposed on an object surface by using an apparatus such as the liquid droplet ejecting apparatus 100 shown in FIGS. 1 to 3. As described above, the liquid droplet ejecting apparatus 100 is an apparatus for dropping the liquid droplets D of the functional liquids 14 and 15 at arbitrary positions on the object surface. Here, the liquid droplets D are ejected from the nozzles 118 of the head 114 in the liquid droplet ejecting apparatus 100 in accordance with ejection data supplied to the liquid droplet ejecting apparatus 100. In the embodiment, for each “inkjet sub-process”, the corresponding liquid droplet ejecting apparatus 100 is used. However, through all of the “inkjet sub-processes” in the inkjet process, a single liquid droplet ejecting apparatus 100 may be used.

Furthermore, in some cases, the “inkjet sub-process” may be defined as including a process for making an object surface lyophilic with respect to the functional liquids 14 and 15. Alternatively, the “inkjet sub-process” may be defined as including a process for making the object surface lyophobic with respect to the functional liquids 14 and 15.

Furthermore, the “inkjet sub-process” may be defined as including a process for drying or activating layers or patterns of the functional liquids 14 and 15 so that an insulating layer, an insulating pattern, a conductive layer or a conductive pattern can be obtained from the layers or patterns of the functional liquids 14 and 15 disposed on the object surface. In this case, the “activation” corresponds to at least one of a process for heating the layers or patterns of the functional liquids 14 and 15 and a process for irradiating an electromagnetic wave of ultraviolet light or the like thereto. In short, the “activation” is a process for developing desired properties including insulating properties, conductivity or semiconductivity from the layers or patterns of the functional liquids 14 and 15 in accordance with materials in the functional liquids 14 and 15.

Then, in the specification, the above-described one or more “inkjet sub-processes” are collectively referred to as the “inkjet process”.

Next, as shown in FIG. 4E, a plurality of dummy posts 5 is disposed on the insulating pattern 4 by the inkjet process. Here, the dummy posts 5 are disposed in such a manner that the top thereof is positioned at approximately the same level as the top of the conductive post 3. Each of the dummy posts 5 is composed in a manner containing a conductive material having high adhesiveness to a conductive pattern 7, which will be described later. In this embodiment, since the conductive pattern 7 is made of silver, each dummy post 5 is also composed containing silver. Accordingly, each of the dummy posts 5 and the conductive pattern 7 can be adhered to each other.

Furthermore, since each of the dummy posts 5 is formed by the inkjet process, a cross-sectional configuration thereof becomes tapered. Specifically, a bottom width of each dummy post 5 becomes greater than a top width thereof. Meanwhile, details of the inkjet process for disposing the plurality of dummy posts 5 will be given later referring to FIGS. 6A to 6E.

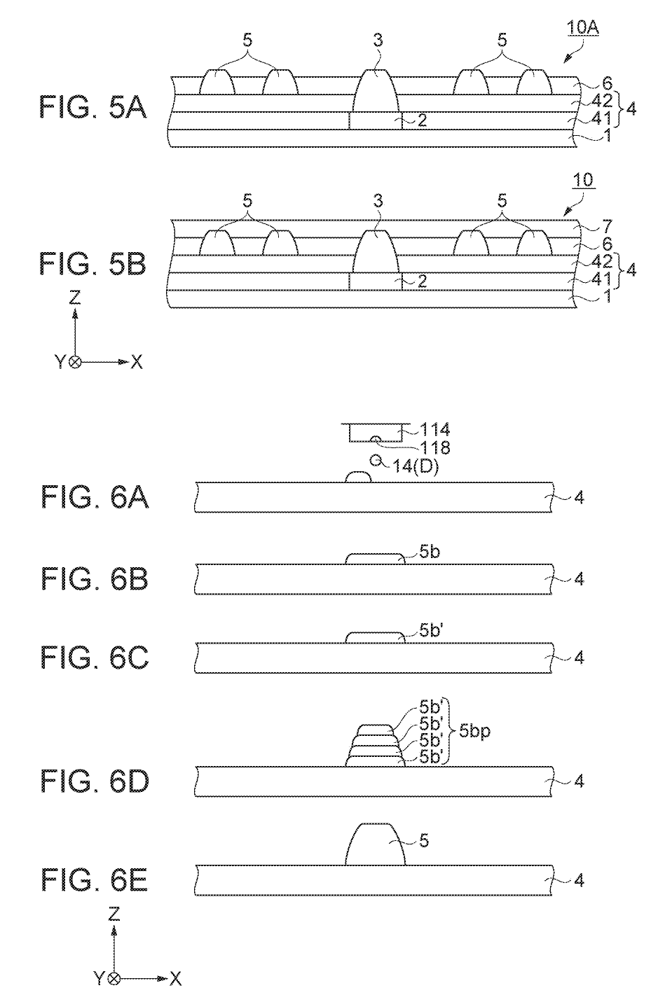

Next, as shown in FIG. 5A, an insulating pattern 6 is disposed on the insulating pattern 4 by the inkjet process. The insulating pattern 6 surrounds a side surface of each of the dummy posts 5 and a side surface of the conductive post 3 protruding on the insulating pattern 4. Here, a thickness of the insulating pattern 6 is set in such a manner that the upper part of each dummy post 5 and the upper part of the conductive post 3 are exposed from the insulating pattern 6. The inkjet process for disposing the insulating pattern 6 will be described later referring to FIGS. 7A to 7C.

When the insulating pattern 6 is disposed as above, the plurality of dummy posts 5 is not detached from the insulating pattern 6, even if an external force is applied to the dummy posts 5 in the Z-axial direction to take the dummy posts 5 away from the insulating pattern 6. That is, each dummy post 5 can be fixed to the insulating pattern 6.

Still furthermore, as will be described later, the insulating pattern 6 is composed to contain an insulating material having high adhesiveness with respect to the insulating pattern 4. Specifically, the insulating pattern 4 is composed to contain acrylic resin, and similarly the insulating pattern 6 contains acrylic resin. As a result, the insulating pattern 6 and the insulating pattern 4 are adhered to each other. In short, the insulating pattern 6 is fixed with respect to the insulating pattern 4.

Next, as shown in FIG. 5B, on the insulating pattern 6, the conductive pattern 7 is disposed by the inkjet process, where the conductive pattern 7 is connected to the upper part of each of the dummy posts 5 and also connected to the upper part of the conductive post 3. In this embodiment, with the process, a multilayered structure 10 can be obtained from the base body 10A. Here, the conductive pattern 7 contains silver. As described above, since each of the dummy posts 5 also contains silver, the conductive pattern 7 and each of the dummy posts 5 can be adhered to each other. In short, the conductive pattern 7 is fixed to the dummy posts 5.

As described above, since each of the dummy posts 5 is fixed to the insulating pattern 6, the conductive pattern 7 is also fixed to the insulating pattern 6. Moreover, the insulating pattern 6 is fixed to the insulating pattern 4. Consequently, the conductive pattern 7 is fixed with respect to the insulating pattern 4 located farther below.

6. Inkjet Process for Disposing Dummy Posts

Referring to FIGS. 6A to 6E, a more detailed explanation will be given of the inkjet process for disposing the plurality of dummy posts 5 shown in FIG. 4E. In the explanation below, for illustrative convenience, the process will be described focusing on a single dummy post 5. However, in fact, the process provides the plurality of dummy posts 5.

As shown in FIG. 6A, the functional liquid 14 containing a conductive material is supplied on the insulating sub-pattern 42, namely, the insulating pattern 4 by using the liquid droplet ejecting apparatus 100 (shown in FIG. 1). More specifically, the liquid droplet ejecting apparatus 100 moves at least one of the head 114 and the base body 10A relatively with respect to the other. Then, when the nozzles 118 of the head 114 are present within a region corresponding to a position at which the dummy posts 5 should be disposed, the liquid droplet ejecting apparatus 100 ejects the liquid droplets D of the functional liquids 14 from the nozzles 118 at a predetermined cycle. Then, the ejected liquid droplets D are dropped onto the insulating pattern 4, with the result that a layer 5b of the functional liquid 14 can be obtained as shown in FIG. 6B.

Then, the layer 5b is temporarily dried to obtain a layer 5b′ in a temporarily dry state, as shown in FIG. 6C. The condition in which the layer 5b′ is in a temporarily dry state means a condition in which at least a surface of the layer 5b′ is dry. In order to obtain the temporarily dried layer 5b′, dry air may be blown onto the layer 5b made of the functional liquid 14, or infrared light may be irradiated thereon.

After that, on the temporarily dried layer 5b′, another layer 5b is disposed and then is temporarily dried. Furthermore, with repetition of the process, as shown in FIG. 6D, four layers 5b′ laminated in the Z-axial direction are obtained on the insulating pattern 4. In the embodiment, the four layers 5b′ in the temporarily dried state are collectively referred to as a dummy post precursor 5bp.

Then, the dummy post precursor 5bp is activated. In the embodiment, the base body 10A is heated on a hot plate at 150 degrees centigrade for approximately 30 minutes. Consequently, silver particles in the dummy post precursor 5bp are sintered or fused. As a result, as shown in FIG. 6E, the dummy post 5 can be obtained from the dummy post precursor 5bp.

Now, back to FIG. 6D, surfaces of the layer 5b′ includes a bottom surface contacting with the base, a top surface contacting with a gas phase and side surfaces connecting the top and bottom surfaces and also contacting with the gas phase. The bottom surface, which is in contact with the flat base, is also flat. The top surface is similarly flat. However, a dimension of the top surface is smaller than that of the bottom surface due to influence of a surface tension of the functional liquid 14. Additionally, on such a top surface, another layer 5b′ will be disposed. Thus, the upper layers 5b′ become smaller than the lower layers 5b′.

Because of the reason above, the dummy post precursor 5bp made of the plurality of layers 5b′ has a tapered cross-sectional configuration. As a result, the dummy post 5 obtained from the dummy post precursor 5bp also has a tapered cross-sectional configuration.

Now, in the embodiment, a single dummy post precursor 5bp is composed of the plurality of laminated layers 5b′. However, instead of the structure, a single dummy post precursor 5bp may be composed of a single layer 5b′. In this case, although a height of the dummy post precursor 5bp is limited, the cross-sectional configuration thereof still becomes tapered due to the surface tension of the functional liquid 14. Therefore, the dummy post 5 obtained from the dummy post precursor 5bp also has a tapered cross-sectional configuration.

In this way, the dummy post 5 is formed by the inkjet process. Thus, the cross-sectional configuration of the dummy post 5 becomes tapered. Specifically, the bottom width of the dummy post 5 is greater than the top width thereof. Moreover, as described referring to FIG. 5A, the insulating pattern 6 surrounds the side surface of the dummy post 5 having such a cross-sectional configuration. Accordingly, even when trying to pull out the dumpy post 5 with a force working from the bottom to the top thereof because of the tapered cross-sectional configuration thereof the dummy post 5 will be anchored by the insulating pattern 6. In other words, the cross-sectional configuration of the dummy post 5 creates the anchor effect (a second anchor effect as described below).

7. Inkjet Process for Disposing Insulating Patterns

Referring to FIG. 7, a more detailed explanation will be given of the inkjet process for disposing the insulating pattern 6 shown in FIG. 5A.

First, although it is not shown in the figure, the surface of the insulating sub-pattern 42, namely, the surface of the insulating pattern 4 is made lyophilic with respect to the functional liquid 15 for forming the insulating pattern 6. In the embodiment, light having a wavelength of 172 nm is irradiated onto the insulating pattern 4. Consequently, the surface of the insulating pattern 4 is made lyophilic with respect to the functional liquid 15. Thus, the functional liquid 15 can be wet-spread widely on the insulating pattern 4.

Next, as shown in FIG. 7A, the functional liquid 15 containing an insulating material is supplied on the insulating pattern 4 by using the liquid droplet ejecting apparatus 100 (shown in FIG. 1). More specifically, the liquid droplet ejecting apparatus 100 moves at least one of the head 114 and the base body 10A relatively with respect to the other thereof. When the nozzles 118 of the head 114 are present within a region corresponding to a position at which the insulating pattern 6 should be disposed, the liquid droplet ejecting apparatus 100 ejects the liquid droplets D of the functional liquid 15 from the nozzles 118 at a predetermined cycle. Then, the ejected liquid droplets D are dropped onto the insulating pattern 4, with the result that a layer 6b of the functional liquid 15 can be obtained as shown in FIG. 7B

When disposing the layer 6b, the volume and number of the ejected liquid droplets D are set in such a manner that the insulating pattern 6 to be obtained from the layer 6b later contacts with the side surface of each of the plurality of dummy posts 6 and also contacts with the side surface of the conductive post 3 protruded from the insulating pattern 4. Additionally, the volume and number of the ejected liquid droplets D are set in such a manner that the upper part of each of the dummy posts 5 and the upper part of the conductive post 3 are exposed from the insulating pattern 6.

Next, as shown in FIG. 7B, the layer 6b is hardened. In the embodiment, light having a wavelength of 365 nm is irradiated for only a predetermined time. Then, the irradiation initiates hardening response of an acrylic photosensitive resin as the insulating material in the functional liquid 15. Consequently, the insulating pattern 6 can be obtained from the layer 6b as shown in FIG. 7C.

In this case, hardening of the layer 6b causes shrinkage of the insulating material contained in the functional liquid 15, thereby improving adhesiveness between the insulating pattern 6 and the plurality of dummy posts 5. As a result, when trying to pull out the dummy posts 5 with a force working from the bottom part to the upper part thereof, the dummy posts 5 will be anchored by the insulating pattern 6. Therefore, because of a first anchor effect caused by the shrinkage of the insulating material (hardening shrinkage), each of the dummy posts 5 is fixed to the insulating pattern 6.

Moreover, in the embodiment, each of the dummy posts 5 is disposed by the inkjet process and therefore has the tapered cross-sectional configuration. In other words, the bottom width of each dummy post 5 is greater than the top width thereof. Thus, when the dummy posts 5 are tried to be pulled out with the force working from the bottom to the upper part thereof, the dummy posts 5 will be anchored by the insulating pattern 6. Accordingly, the cross-sectional configuration of each of the dummy posts 5 creates the second anchor effect, with the result that each dummy post 5 is fixed to the insulating pattern 6.

According to the embodiment, the above-mentioned conductive pattern 7 is fixed to the plurality of dummy posts 5. Here, each of the dummy posts 5 is fixed to the insulating pattern 6, whereby the conductive pattern 7 is also fixed with respect to the insulating pattern 6. In addition, the insulating pattern 6 is fixed to the insulating pattern 4. As a result, the conductive pattern 7 is also fixed with respect to the insulating pattern 4 farther below.

### Second Embodiment

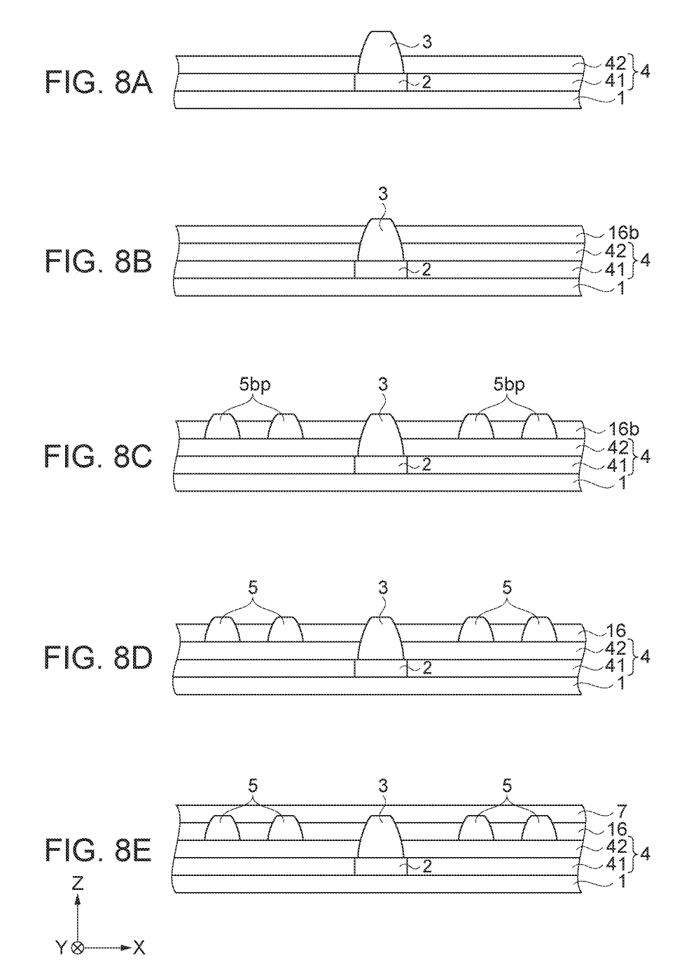

Referring to FIGS. 8A to 8E, a description will be given of a multilayered structure forming method according to a second embodiment of the invention.

The multilayered structure forming method of the second embodiment is basically the same as that of the first embodiment, except for a method for forming the dummy posts 5 and a method for forming an insulating pattern 16. Therefore, the same structural elements as those in the first embodiment are provided with the same reference numerals as those therein. In order to prevent overlapping explanation, a detailed description of the same elements is omitted here.

First, the conductive post 3 and the insulating pattern 4 surrounding the lower part of the side surface thereof are disposed by the process described referring to FIGS. 4A to 4D in the first embodiment (See FIG. 8A). As mentioned above, the insulating pattern 4 in the embodiment is composed of the two mutually laminated insulating sub-patterns 41 and 42.

Next, as shown in FIGS. 8B to 8D, the plurality of dummy posts 5 and the insulating pattern 16 surrounding the side surface of each of the dummy posts 5 are disposed on the insulating pattern 4 by the inkjet process. Specifically, the process is performed as follows.

First, the functional liquid 15 containing an insulating material is supplied on the insulating pattern 4 by using the liquid droplet ejecting apparatus 100. More specifically, the liquid droplet ejecting apparatus 100 moves at least one of the head 114 and the base body 10A relatively with respect to the other thereof. Then, when the nozzles 118 of the head 114 are present within a region corresponding to a position at which the insulating pattern 16 should be disposed, the liquid droplet ejecting apparatus 100 ejects the liquid droplets D of the functional liquid 15 from the nozzles 118 at a predetermined cycle. Then, the ejected liquid droplets D are dropped onto the insulating pattern 4, with the result that a layer 16b of the functional liquid 15 can be obtained as shown in FIG. 5B.

Then, before hardening the layer 16b, the functional liquid 14 containing a conductive material is supplied by using the liquid droplet ejecting apparatus 100. Specifically, the liquid droplet ejecting apparatus 100 moves at least one of the head 114 and the base body 10A relatively with respect to the other thereof. Then, when the nozzles 118 of the head 114 are present in a region corresponding to a position at which the dummy posts 5 should be disposed, the liquid droplet ejecting apparatus 100 ejects the liquid droplets D of the functional liquid 14 from the nozzles 118 at a predetermined cycle.

Here, since the layer 16b is not hardened, the liquid droplets D of the ejected functional liquid 14 sink into the layer 16b. Thus, each of the dummy post precursors 5bp made of the ejected functional liquid 14 is buried in the layer 16b as shown in FIG. 8C.

In this manner, a side surface of each of the dummy post precursors 5bp is surrounded by the layer 16b. Meanwhile, the thickness of the layer 16b and the height of each of the dummy post precursors 5bp are set in such a manner that the upper part of each of the dummy posts 5 is exposed from the below-mentioned insulating pattern 16.

Next, the layer 16b and the plurality of dummy post precursors 5bp are activated simultaneously. In this embodiment, the layer 16b and the dummy post precursors 5bp are simultaneously heated. Then, the insulating material of the layer 16b is hardened, as well as silver particles contained in each of the dummy post precursors 5bp are sintered or fused. Thus, because of the activation, as shown in FIG. 8D, the insulating pattern 16 can be obtained from the layer 16b and also the plurality of dummy posts 5 can be obtained from the dummy post precursors 5bp.

Here, since the plurality of dummy posts 5 is disposed by the inkjet process, each of the dummy posts 5 has a tapered cross-sectional configuration, as described in the first embodiment. Specifically, the bottom width of each of the dummy posts 5 is greater than the top thereof. Additionally, since the side surface of each dummy post 5 having such a configuration is surrounded by the insulating pattern 16, the dummy posts 5 are fixed to the insulating pattern 16.

Next, the conductive pattern 7 is disposed on the insulating pattern 16 by the inkjet process, in which the conductive pattern 7 is connected to the upper part of each dummy post 5 and the upper part of the conductive post 3 (See FIG. 8E). As described in the first embodiment, the conductive pattern 7 and each of the dummy posts 5 both contain silver, with the result that they can be adhered to each other. That is, the conductive pattern 7 is fixed to the dummy posts 5.

Here, since each of the dummy posts 5 is fixed to the insulating pattern 16, the conductive pattern 7 is also fixed with respect to the insulating pattern 16. Moreover, the insulating pattern 16 is fixed to the insulating pattern 4, with the result that the conductive pattern 7 is also fixed with respect to the insulating pattern 4 farther below.

### Third Embodiment

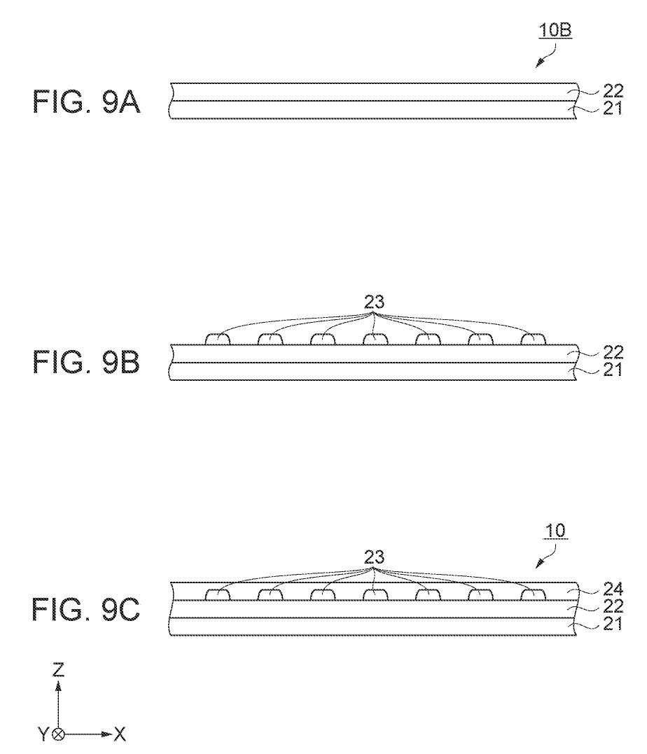

Referring to FIGS. 9A to 9C, a description will be given of a multilayered structure forming method according to a third embodiment of the invention.

First, a base body 10B as shown in FIG. 9A is prepared. Here, the base body 10B includes a substrate 21 and a conductive pattern 22 disposed thereon. The substrate 21 is a flexible substrate made of polyimide and has a tapered configuration. Additionally, the conductive pattern 22 is made of copper (Cu) and is patterned by a photolithographic process. Alternatively, the conductive pattern 22 may be made of gold (Au).

Next, as shown in FIG. 9B, an uneven pattern is disposed on the conductive pattern 22 by the inkjet process.

Specifically, a plurality of dummy posts 23 is disposed on the conductive pattern 22 by the inkjet process. Here, the inkjet process for forming the dummy posts 23 is basically the same as that for forming the plurality of dummy posts 5 (shown in FIGS. 6A to 6E). In other words, the plurality of dummy posts 23 can be obtained by the process in which a plurality of dummy post precursors is formed by ejecting the functional liquid 14 and then is activated, namely, heated. Here, as mentioned above, the functional liquid 14 contains silver as a conductive material. In addition, silver has high adhesiveness to the conductive pattern 22 made of copper. Accordingly, each of the obtained dummy posts 23 can be adhered to the conductive pattern 22.

Now, each of the dummy posts 23 is of a nearly truncated-cone configuration. In this embodiment, the height of each dummy post 23 is approximately half the height (thickness) of the conductive pattern 22. In the embodiment, the uneven pattern is formed by the surface of the conductive pattern 22 and the plurality of dummy posts 23 disposed thereon.

Next, as shown in FIG. 9C, an insulating pattern 24 is disposed by the inkjet process. In this case, the insulating pattern 24 is disposed in a manner that covers the substrate 21, the conductive pattern 22 and the plurality of dummy posts 23. Furthermore, the inkjet process for disposing the insulating pattern 24 is basically the same as that for disposing the insulating pattern 6 (shown in FIGS. 7A to 7C). In other words, the insulating pattern 24 can be obtained by the process in which a layer of the ejected functional liquid 15 is formed and then activated, namely, hardened. Here, as mentioned above, the functional liquid 15 contains acrylic photosensitive resin as an insulating material. The acrylic resin has high adhesiveness to the substrate 21 made of polyimide. Thus, the obtained insulating pattern 24 adheres to the substrate 21.

Here, if there is no dummy post 23 on the conductive pattern 22, the insulating pattern 24 will be in contact directly with the surface of the conductive pattern 22. Since the conductive pattern 22 is formed by a photolithographic method, the surface thereof is a highly flat, glossy surface. It is difficult for the insulating pattern 24 to adhere to the conductive pattern 22 having such a surface. Therefore, even locally, the obtained multilayered structure 10 results in having an easily separatable part.

In the third embodiment, however, the insulating pattern 24 covers the uneven pattern formed by the surface of the conductive pattern 22 and the dummy post 23. This improves adhesiveness between the conductive pattern 22 and the insulating pattern 24. One reason for this is as follows: since the inkjet process for disposing the insulating pattern 24 includes the process for hardening the layer of the functional liquid 15, the insulating material (acrylic resin) is hardened and shrunk. As a result, the obtained insulating pattern 24 has an anchor effect on the uneven pattern. Because of the effect, the insulating pattern 24 adheres to the conductive pattern 22.

Therefore, according to the multilayered structure forming method according to the third embodiment, the insulating pattern 24 can be obtained that is not easily separatable from the underlying conductive pattern 22.

First Modification

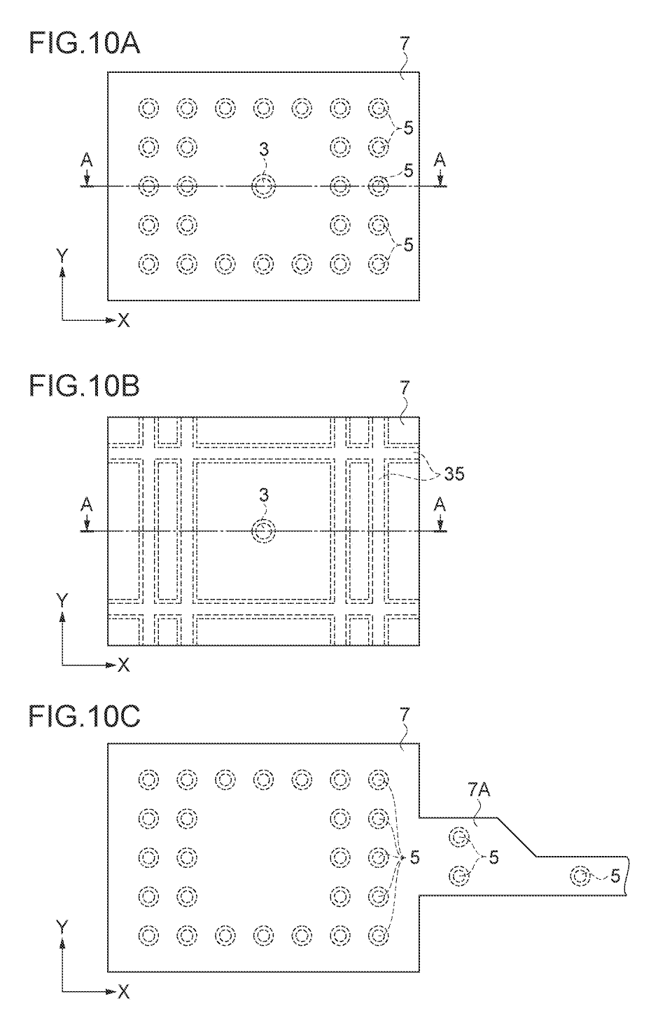

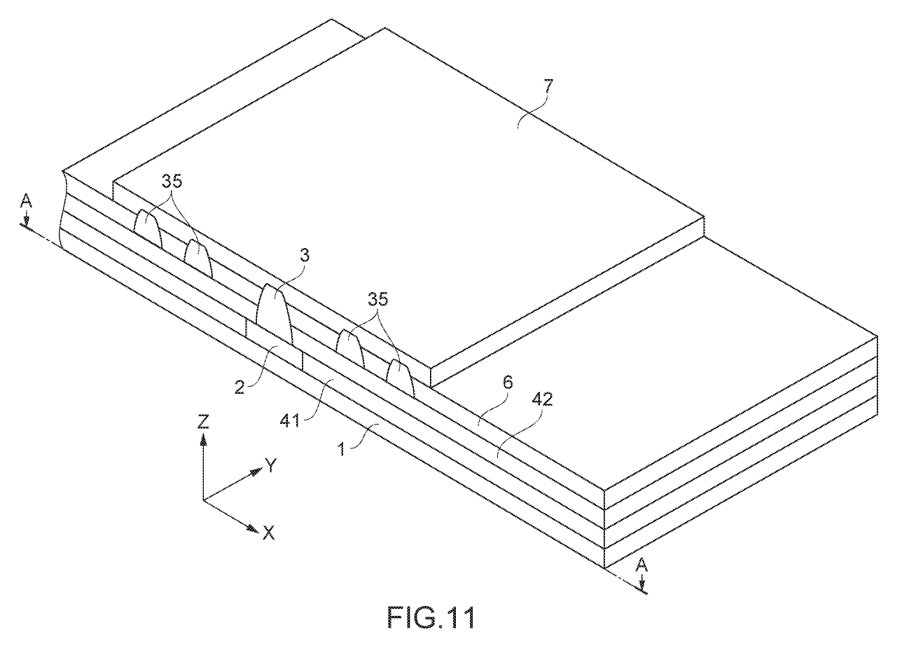

Each of the dummy posts 5 in the first and second embodiments is of an approximately truncated cone configuration. Because of the configuration, the cross-section of the dummy posts 5 is tapered (See FIG. 10A). However, the configuration of the “dummy post” in the invention is not limited to the truncated cone. Specifically, as long as the cross-section of the “dummy post” is tapered, the configuration thereof does not have to be a truncated cone.

For example, each of dummy posts 35 shown in FIG. 10B and FIG. 11 has a striped configuration extending in the X or Y-axial direction. Even when the dummy post 35 has a striped configuration, as long as the dummy post is disposed by the inkjet process, the dummy post will have a tapered cross-sectional configuration. In short, a bottom width of the dummy post 35 becomes greater than a top width thereof.

If the dummy post 35 is formed in a striped configuration, an area in which the dummy post 35 is in contact with the conductive pattern 7 will be larger than in the case of the dummy post 5 in the truncated cone configuration. Accordingly, striped configuration can increase adhesiveness between the dummy post 35 and the conductive pattern 7. Additionally, a paper surface in FIGS. 10A and 10B is parallel to an XY plane.

Second Modification

In the first and second embodiments, the conductive pattern 7 is a connection land. Additionally, a combination of the conductive post 3 and the plurality of dummy posts 5 serves to fix the conductive pattern 7. However, the present invention is not limited to those embodiments. For example, as shown in FIG. 10C, only the dummy posts 5 may serve to fix the connection land. In short, the conductive post 3 may be unnecessary. Furthermore, the subject to be fixed by the dummy posts 5 is not limited to a connection land and may be a striped conductive pattern 7A. Additionally, a paper surface in FIG. 10C is parallel to the XY plane.

Third Modification

The functional liquid 14 in the first through third embodiments contains silver nanoparticles. However, instead of the silver nanoparticles, other metallic nanoparticles may be used. Here, as another alternative metal, for example, the invention may use one of gold, platinum, copper, palladium, rhodium, osmium, ruthenium, iridium, iron, tin, zinc, cobalt, nickel, chrome, titanium, tantalum, tungsten and indium. Alternatively, an alloy that combines any two or more of those metals may be used. However, since silver can be reduced at a relatively low temperature, it is easy to use. In this respect, when using the liquid droplet ejecting apparatus 100, it is desirable to use the functional liquid 14 containing silver nanoparticles.

Furthermore, the functional liquid 14 may contain an organometallic compound instead of metallic nanoparticles. In this case, the organometallic compound means a chemical compound whose metal deposition is performed by thermal decomposition. Such organometallic compounds include chlorotriethylphosphine gold (I), chlorotrimethylphosphine gold (I), chlorotriphenylphosphine gold (I), silver (I) 2,4-pentanedionato complex, trimethylphosphine (hexafluoroacetylacetonato) silver (I) complex, and copper (I) hexafluoropentanedionatocyclooctadiene complex.

As mentioned above, the metal contained in the functional liquid 14 may be in the form of particles as typified by nanoparticles, or may be in a form of compound such as an organometallic compound.

Furthermore, the functional liquid 14 may contain a soluble polymeric material such as polyaniline, polythiophene or poly-phenylene-vinylene, instead of metal.

Fourth Modification

As described in the first embodiment, the silver nanoparticles in the functional liquid 14 may be coated with a coating agent such as an organic matter. As the coating agent, aminie, alcohol, thiol, etc. are known. More specifically, such coating agents include amine compounds such as 2-methylaminoethanol, diethanolamine, diethylmethylamine, 2-dimethylaminoethanol, methyldiethanolamine, alkylamines, ethylenediamine, alkylalcohols, ethyleneglycol, propyleneglycol, alkylthiols and ethanedithiol. The nanoparticles of silver coated with a coating agent can be dispersed in a more stable manner in a dispersion medium.

Fifth Modification

According to the first to third embodiments, irradiation of light having an ultraviolet wavelength makes the surfaces of the substrates 1, 21 and the insulating pattern 4 lyophilic. However, as an alternative to such a lyophilic process, O₂ plasma process, in which oxygen is used as a process gas in an ambient atmosphere, may be performed to make those surfaces lyophilic. The O₂ plasma process is a process in which oxygen in a plasma state is irradiated to an object surface from a plasma discharge electrode which is not shown in the figures. Minimum requirements of the O₂ plasma process may include a plasma power from 50 to 1000 W, an oxygen gas flow rate of 50 to 100 mL/min, a relative moving velocity of an object surface with respect to a plasma discharge electrode of 0.5 to 10 mm/sec and a temperature of the object surface ranging from 70 to 90 degrees Centigrade.

Sixth Modification

In each of the first to third embodiments, the multilayered structure forming method can be realized by using the plurality of liquid droplet ejecting apparatuses 100. However, a single liquid droplet ejecting apparatus 100 may be used for performing the multilayered structure forming method according to the invention. In this case, it is only necessary for the single liquid droplet ejecting apparatus 100 to simply eject a different liquid material 111 from each head 114.

Seventh Modification

In the first to third embodiments, the functional liquid 15 contains the solvent and the acrylic photosensitive resin as the insulating material. In short, the functional liquid 15 contains the polymer dissolved in the solvent.

However, instead of such a composition, the functional liquid 15 may contain a precursor of an insulating material. For example, the functional liquid 15 may contain a photo initiator, a monomer having a polymer functional group such as a vinyl group or an epoxy group, and/or an oligomer. Alternatively, for example, the functional liquid 15 may be an organic solution containing a monomer having a photo functional group. Here, as the monomer having a photo functional group, a photo-curing imide monomer may be used. Furthermore, for example, when a monomer as the insulating resin material has liquidity appropriate for ejection from the nozzles 118, the monomer itself (namely, the monomer liquid) may be used as the functional liquid 15 as an alternative to an organic solution containing the monomer dissolved therein. Even with the use of such a functional liquid 15, the insulating pattern or the insulating sub-pattern used in the invention can be formed. Accordingly, the functional liquid 15 for disposing the insulating pattern may contain a precursor of the insulating material.

Alternatively, the functional liquid 15 may contain an inorganic insulating material such as SiO₂ as the insulating material. That is, the obtained insulating pattern 6 does not have to be an “insulating resin”. This is because as long as the dummy posts 5 and 35 have tapered cross-sectional configurations, the anchor effect can be obtained even when the insulating pattern 6 is made of a material other than an insulating resin.

Eighth Modification

In the first and second embodiments, the multilayered structure 10 is composed of five layers laminated in the Z-axial direction from the substrate 1 as the lowest layer to the conductive pattern 7 as the top surface layer. However, in fact, between the substrate 1 and the insulating pattern 4, there may be disposed many more layers. In other words, the “object surface” in the invention may be the surface of the substrate 1, or may be otherwise a surface of any of the insulating layers or patterns. Furthermore, in the multilayered structure 10, an electronic component such as resistor, a capacitor, an LSI bare chip or an LIS package may be embedded between the plurality of insulating layers or insulating patterns. Still furthermore, the same effects as those described in the above embodiments can be obtained also by using an alternative to the substrate 1 made of polyimide, for example, a ceramic substrate, a glass substrate, an epoxy substrate, a glass epoxy substrate or a silicon substrate.

What is claimed is:

1. A multilayered structure forming method comprising:
disposing a dummy post on a first insulating pattern as a first inkjet process;
disposing a second insulating pattern on the first insulating pattern so as to allow the second insulating pattern to surround a side surface of the dummy post as a second inkjet process; and
disposing a first conductive pattern on the second insulating pattern so as to connect the first conductive pattern to the dummy post as a third inkjet process; wherein the first inkjet process includes a process for ejecting a functional liquid containing a first conductive material having high adhesiveness to the first conductive pattern onto the first insulating pattern.

2. The multilayered structure forming method according to claim 1, wherein the second inkjet process includes a process for ejecting one of a functional liquid containing a predetermined insulating material having high adhesiveness to the first insulating pattern and a functional liquid containing a precursor of the predetermined insulating material having high adhesiveness to the first insulating pattern onto the first insulating pattern.

3. The multilayered structure forming method according to claim 2, further comprising: disposing the first insulating pattern on an object surface as a fourth inkjet process.

4. The multilayered structure forming method according to claim 2, wherein the first insulating pattern is comprised of a same material as the predetermined insulating material.

5. The multilayered structure forming method according to claim 1, wherein the first conductive material is same as a material of the first conductive pattern.

6. The multilayered structure forming method according to claim 1, wherein the first conductive material includes a same metal as the first conductive pattern.

7. The multilayered structure forming method according to claim 3, further comprising:
disposing a conductive post on a second conductive pattern disposed on the object surface as a fifth inkjet process;
disposing the first insulating pattern on the object surface as the fourth inkjet process so as to allow the first insulating pattern to cover the second conductive pattern and surround a lower part of a side surface of the conductive post;
insulating pattern on the first insulating pattern as the second inkjet process so as to allow the second insulating pattern to surround a remaining part of the side surface of the conductive post and the side surface of the dummy post; and
disposing the first conductive pattern on the second insulating pattern as the third inkjet process so as to connect the first conductive pattern to the conductive post and the dummy post.

8. The multilayered structure forming method according to claim 1, wherein the third inkjet process includes a process for disposing a connection land as the first conductive pattern.

9. The multilayered structure forming method according to claim 1, wherein the third inkjet process includes a process for disposing a top surface layer of a multilayered structure as the first conductive pattern.

10. A multilayered structure forming method comprising:
disposing a dummy post and a second insulating pattern surrounding a side surface of the dummy post as a first inkjet process; and
disposing a first conductive pattern on the second insulating pattern as second inkjet process so as to connect the first conductive pattern to the dummy post, wherein the first inkjet process includes:
(a) forming a layer of a functional liquid by ejecting one of the functional liquid containing a predetermined insulating material and the functional liquid containing a precursor of the predetermined insulating material onto a first insulating pattern as a first process; and
(b) forming a dummy post precursor by ejecting a functional liquid containing a first conductive material having high adhesiveness to the dummy post onto the layer of the functional liquid as a second process

11. The multilayered structure forming method according to claim 10, wherein the first inkjet process further includes:
(c) activating the layer of the functional liquid and the dummy post precursor simultaneously so as to obtain the second insulating pattern from the layer of the functional liquid and the dummy post from the dummy post precursor, respectively as a third process.

12. The multilayered structure forming method according to claim 10, wherein the first process includes a process for ejecting one of the functional liquid containing the predetermined insulating material having high adhesiveness to the first insulating pattern and the functional liquid containing the precursor of the predetermined insulating material having high adhesiveness to the first insulating pattern onto the first insulating pattern.

13. The multilayered structure forming method according to claim 12, further comprising a third inkjet process for disposing the first insulating pattern on an object surface.

14. The multilayered structure forming method according to claim 12, wherein the first insulating pattern is comprised of a same material as the predetermined insulating material.

15. The multilayered structure forming method according to claim 10, wherein the first conductive material is same as a material of the first conductive pattern.

16. The multilayered structure forming method according to claim 10, wherein the first conductive material includes a same metal as the first conductive pattern.

17. A multilayered structure forming method comprising:
disposing an uneven pattern on a conductive pattern disposed on a surface of a substrate and comprised of a first conductive material as a first inkjet process; and
disposing an insulating pattern covering the conductive pattern and the uneven pattern as a second inkjet process.
